(19) United States
(12) Patent Application Publication
(10) Pub. No.: US 2021/0278476 A1
(43) Pub. Date: Sep. 9, 2021

(54) System and Method of Fault Detection Based on Robust Damped Signal Demixing

(71) Applicant: Mitsubishi Electric Research Laboratories, Inc., Cambridge, MA (US)

(72) Inventors: Dehong Liu, Lexington, MA (US); Youye Xie, Golden, CO (US); Hassan Mansour, Boston, MA (US); Petros Boufounos, Winchester, MA (US)

(73) Assignee: Mitsubishi Electric Research Laboratories, Inc., Cambridge, MA (US)

(21) Appl. No.: 16/812,696

(22) Filed: Mar. 9, 2020

(51) Int. Cl. G01R 31/52; H02K 11/20; G01R 31/34

(52) U.S. Cl. CPC G01R 31/52; G01R 31/34; H02K 11/20

(57) ABSTRACT

A system for detecting faults of an electric machine is provided. The system includes an interface, a memory to store computer-implemented programs including a signal sampling program, a matrix formation program, an optimization formation program, a matrix pencil program, optimization solvers and lookup data including predetermined system parameters related to the faults, and a processer. The processor performs, using the computer-implemented programs, generating a signal matrix based on the acquired signals for the input time domain, forming an optimization problem with a low-rank constraint using the optimization formation program, demixing the signal matrix into a low-rank matrix, a spike interference matrix, and a Gaussian noise matrix by solving the optimization problem using one of the optimization solvers, extracting parameters of damped exponentials from the low-rank matrix using the matrix pencil program, and determining the faults with respect to the induction machine by identifying each of the measured system parameters of the induction machine based on the lookup data.

### FIELD OF THE INVENTION

The present invention relates, generally, to system and method of monitoring electric machines, and, more particularly, to system and method of fault detection in electric machines based on robust damped signal demixing.

### BACKGROUND

Electric machines are widely used in a variety of application areas such as power plants, manufacturing factories, home appliances, electric vehicles, and the like. Electric machines can experience a variety of faults such as bearing faults, broken rotor bar faults, and winding short-circuit faults. These faults may reduce the life cycle of electrical machines and even cause sudden catastrophic failure. For example, bearing faults can cause excessive vibrations and frictions when the electrical machine is running at high velocity. Therefore, there is a need to detect a fault in the electric machines to reduce the losses caused by such faults.

### SUMMARY

Different techniques for fault detection that are employed at present include, but are not limited to, vibration and acoustic signal analysis, electromagnetic field monitoring, temperature measurement, infrared recognition, and stator current spectral analysis.

In order to on-line monitor electric machine operation and instantly detect faults, it is necessary to analyze time sequential signal (vibration or current signal) of rotating electric machines and extract characteristic fault signatures for further analysis. However, due to the noisy working environment and changing load of electric machines, the measured signals are typically a mix of normal operating signal, fault signal, spike interferences, transient signal due to sudden change of load or supply voltage, and white Gaussian noise. For example, the magnitude of fault signatures can vary at different loads even if the fault signatures in the stator current are already subtle. As a result, it can be difficult to distinguish fault signatures from the normal operation signal and noise.

In order to decompose signal and detect fault signatures, classical methods such as Fourier transform and Wavelet transform work well for static operations. While for electric machines working in transient state, these classical methods perform poorly in extracting the fault signature due to its changing magnitude.

The Hilbert-Huang transform (HHT) is another way to decompose a signal and to analyze components. The HHT uses the empirical mode decomposition (EMD) to decompose a signal into so-called intrinsic mode function (IMF) with a trend, and applies Hilbert spectral analysis (HSA) method to the IMFs to obtain instantaneous frequency data. The HHT method is designed to work well for data that is nonstationary and nonlinear. However, it is more like an empirical approach without theoretical guarantee.

Another technique of the fault signature detection is based on the compressive sensing. Such a technique is making use of the super-resolution property of compressive sensing techniques to extract fault signature in a very short time such that the electric machine can be assumed to operate at a steady condition in the short time.

According to an embodiment of the present invention, a method detects faults during an operation of an electric machine is provided. The method measures, in a time domain, a signal of a stator current powering the electric machine, wherein the measuring includes sampling the signal for a period of time during the operation of the induction motor with a sampling rate of at least twice of a fundamental frequency of the stator current; a processor for demixing, in a time domain, a set of damped signals with non-zero amplitudes, spike interference, and noise, such that the set of damped signals include a fundamental frequency of operating signal, one or more possible fault signals, and other harmonic damped signals, and determining, a fault signal corresponding to a potential fault according to the signal frequency and magnitude. The method detects a fault in the electric machine if the set of damped signals includes a fault characteristic frequency corresponding to a fault.

Some embodiments of the present invention can provide a system and a method suitable for performing a fault detection of an electric machine based on analysis the stator current powering the electric machine during the operation of the electric machine or the vibration signal of the electric machine. In such a manner, the fault detection can be performed continuously and concurrently with the operation of the electric machine, and without a need for restarting the electric machine.

Further, some embodiments of the present invention provide such a system and a method that can perform the fault detection by measuring noisy signal of the electric machine, where the electric machine may be interfered by spike interference and have changing load condition.

Some embodiments of the invention are based on recognitions that under fault conditions the resulting stator current powering the induction motor is a mix of damped exponential signals, white Gaussian noise and spike interference. This is because the stator current includes harmonics of a fundamental frequency of a power supply generating the stator current and fault frequency components caused by the fault. The spike interference is cause by changing load or working conditions or some other interferences.

Some embodiments of the invention are based on recognitions that parameter estimation of damped exponentials has been extensively studied in the noiseless setting. Well-established methods for solving this problem include the Prony's method, which contains a polynomial root finding operation, and the matrix pencil method, which forms a matrix pencil based on the input signal and solves a generalized eigenvalue problem. However, both methods are very sensitive to noise.

Some embodiments of the invention are based on recognitions that data pre-processing methods based on singular value decomposition (SVD) of a Hankel matrix have been proposed for the matrix pencil method and have been found superior for denoising if the noise is random Gaussian.

Some embodiments of the invention are based on recognitions that a Hankel matrix constructed of a sum of damped exponentials is low-rank.

Some embodiments of the invention are based on recognitions that Robust principle component analysis (RPCA) has been proved to be very effective in extracting a low-rank matrix from spike interference contaminated observation.

These recognitions lead to a realization that the combination of the demixing damped signals using a matrix pencil, RPCA, spike noise, and Gaussian noise enable reconstruction of the actual signal using sparsity-driven techniques to denoise a low-rank Hankel matrix for the matrix pencil method.

Accordingly, one embodiment of the invention discloses a method for detecting faults during an operation of an electric machine. The method includes measuring, in a time domain, a signal of a current powering the electric machine; demixing, a set of damped signals with non-zero amplitudes, spike interference, and noise, such that the set of damped signals include a fundamental frequency of operating signal, one or more possible fault signals, and other harmonic damped signals, and determining, a fault signal corresponding to a potential fault according to the signal frequency and magnitude.

The demixing includes forming, a Hankel matrix of time-domain measurements, denoising, using a convex robust parameter estimation (CRPE) or a non-convex robust parameter estimation (NRPE) method to denoise a Hankel matrix, analyzing, using a matrix pencil method on the denoised Hankel matrix to achieve parameters of damped signals. The steps of the method are performed by a processor.

Another embodiment discloses a system for operating an electric machine including a power supply for powering the electric machine with a stator current having a fundamental frequency; a sensor for measuring, in a time domain, a signal of a stator current powering the electric machine, wherein the measuring includes sampling the signal for a period of time during the operation of the induction motor with a sampling rate of at least twice of a fundamental frequency of the stator current; a processor for demixing, in a time domain, a set of damped signals with non-zero amplitudes, spike interference, and noise, such that the set of damped signals include a fundamental frequency of operating signal, one or more possible fault signals, and other harmonic damped signals, and determining, a fault signal corresponding to a potential fault according to the signal frequency and magnitude.

### BRIEF DESCRIPTION OF THE DRAWINGS

The presently disclosed embodiments will be further explained with reference to the attached drawings. The drawings shown are not necessarily to scale, with emphasis instead generally being placed upon illustrating the principles of the presently disclosed embodiments.

FIG. 1A is a block diagram of a system for detection of faults in the electric machine during operation according to embodiments of the invention;

FIG. 1B is a drawing for describing a system for detection of faults in the electric machine during operation according to embodiments of the invention;

FIG. 2 is a block diagram of a method for detecting the faults in the electric machine according to one embodiment of the invention;

FIG. 3 is a block diagram of a method for denoising the Hankel matrix of measurements according to another embodiment of the invention; and

FIG. 4 is exemplar plots of a signal of a stator current powering the electric machine and demixed damped signals including a fundamental operating frequency component, a fault signature damped signal, a Gaussian noise, and a spike interference.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTIONS

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed, but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

### Embodiments of the Present Disclosure

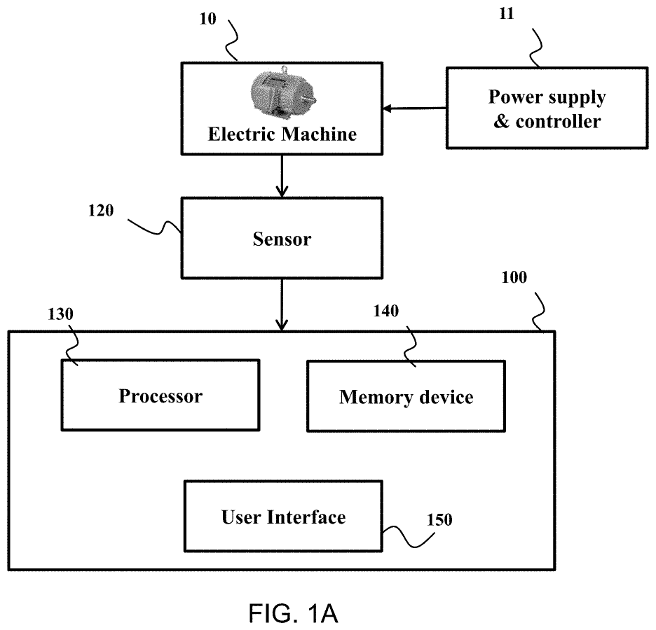

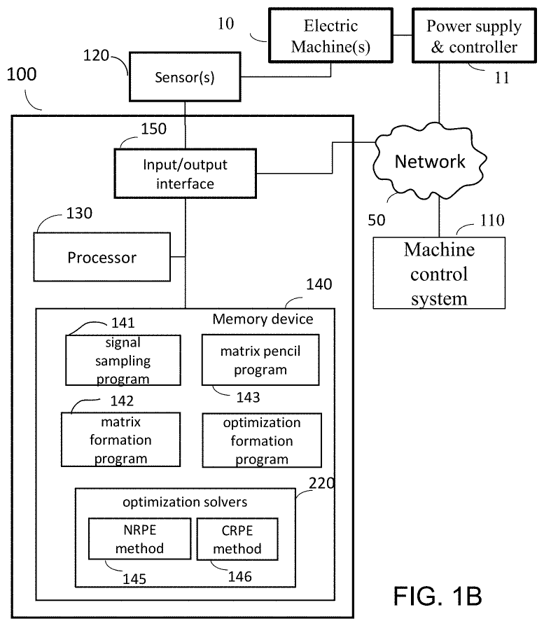

FIG. 1A is a schematic of a system 100 for monitoring an exemplar electric machine according to one embodiment of an invention. In this example, the electric machine 10, which is operated via a power supply & controller 11, is asynchronized machine or synchronized machine with a rotating rotor and a fixed stator.

The system 100 includes a sensor (electrical signal sensors) 120 for measuring, in a time domain, a signal of a stator current powering the electric machine (or induction motor) 10. The measuring includes sampling the signal for a period of time during a steady state of the operation of the induction motor with a sampling rate of at least twice of a fundamental frequency of the stator current. According to certain embodiments, the electrical signal sensors 120 can be current or vibration sensors for acquiring current and vibration data pertaining to the electric machine 10. For example, the sensor 120 may be configured to sense current data from one or more of the multiple phases of the electric machine 10. More specifically, in the case of the electric machine is a 3-phase electric machine, the current and voltage sensors sense the current and voltage data from the three phases of the 3-phase electric machine. While certain embodiments of the present invention will be described with respect to a multi-phase electric machine, other embodiments of the present invention can be applied to other multi-phase electric machines.

A processor 130 is configured to determine, in a frequency domain, a set of frequencies with non-zero amplitudes, such that a reconstructed signal formed by the frequencies with non-zero amplitudes approximates the signal measured in the time domain. The determining includes searching within a subband including the fundamental frequency subject to condition of a sparsity of the signal in the frequency domain.

The system 100 also includes a memory device 140 for storing the measurements of the signal and various parameters and coefficients for performing signal analysis.

FIG. 1B is a drawing for describing the system 100 for detection of faults in the electric machine during operation according to embodiments of the invention. The system 100 can also include an input/output interface 150 configured to acquire the signals from the sensor 120, and transmits signals (output data) to a machine control system 110 via a network 50 with respect to the fault, if the set of frequencies with non-zero amplitudes includes a frequency different from the dominant frequency. Further, the memory device 140 includes computer-executable programs for detecting faults of an electric machine. The computer-executable programs include a signal sampling program 141, a matrix formation program 142, a matrix pencil program 143, and optimization solvers 220 that are configured to perform non-convex robust parameter estimation (NRPE) method and a convex robust parameter estimation (CRPE) method using the processor 130. Accordingly, the processor 130 is configured, in response the signals from the sensor(s) 120 via the I/O interface 150, to perform acquiring signals via sensors with respect to the machine for an input time domain, generating a signal matrix based on the acquired signals for the input time domain, forming an optimization problem with a low-rank constraint using a optimization formation program, demixing the signal matrix into a low-rank matrix, a spike interference matrix, and a Gaussian noise matrix by solving the optimization problem using one of optimization solvers, extracting parameters of damped exponentials from the low-rank matrix using the matrix pencil program, and determining the faults with respect to the induction machine by identifying each of the measured system parameters of the induction machine based on the lookup data. The procedures of the steps are described below.

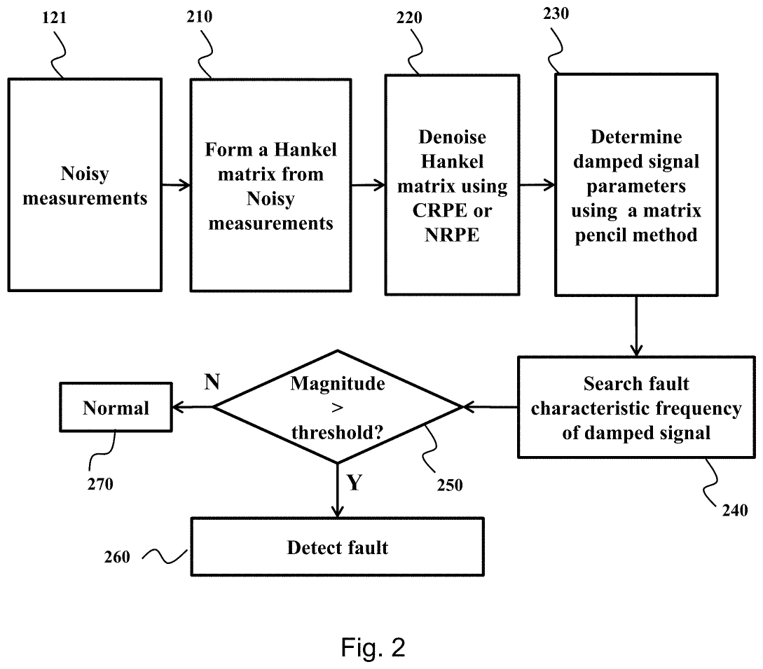

FIG. 2 shows a block diagram of a method for detecting faults during an operation of an electric machine according to one embodiment of the invention. The system 100 detects noisy measurements 121 of a signal of a stator current powering the induction motor measured by the sensor(s) 120 in a time domain to form a noisy Hankel matrix 210. The processor 130 of the system 100 is configured to denoise the noisy Hankel matrix using the CRPE method or non-convex robust parameter estimation (NRPE) method to generate a low-rank Hankel matrix corresponding to a setup of damped signals 220. A matrix pencil method 143 is then applied on the denoised Hankel matrix to determine damped signal parameters 230. The damped signal parameters are used to compare with fault characteristic frequency 240. If there exists a fault frequency and the magnitude is greater than a threshold 250, a corresponding fault is detected 260, otherwise the electric machine is running in normal condition 270.

For instance, the threshold 250 may be determined by the following. When there exists fault frequency component with magnitude greater than a certain value, for example, −30 dB of the fundamental frequency component, and the fault frequency is close to the characteristic fault frequency, for example, within 5% of the characteristic fault frequency, the system 100 detects the fault in step 260. In this case, the characteristic fault frequency can be determined by mechanical structure of electric machine (for example, bearing size and number of balls) and the rotor speed. The greater the magnitude of the fault frequency, the more likely there is a fault, e.g., bearing inner race fault.

Mathematically, the system observes time domain signal

$$y ( t ) = {\sum }_{j = 1}^{M} {A}_{j} {e}^{{α}_{j} t} {e}^{i ( 2 π {f}_{j} t + {θ}_{j} )} + η ( t ) , \qquad ( 1 )$$

where y(t) is the noisy observation consisting of a number of damped exponentials with their amplitude Aⱼ>0, damping coefficient αⱼ≤0^{t}, frequency fⱼ>0, and phase θⱼ∈R, as well as their total number M, being unknown parameters. The noise η(t) can be modeled as a mixture of Gaussian noise, g(t), and sparse spike interference, s(t), i.e., η(t)=g(t)+s(t). In particular, s(t) can be either unwanted interference or a series of system responses with short response time compared to the sampling time, containing valuable information regarding the operating condition of the circuit or the electric machine.

The Hankel matrix Hₚ(x)∈C^{(N-p)×(p+1)} of a sampled signal x∈C^{N}, is defined as

$${H}_{p} ( x ) = [ \begin{matrix}x ( 1 ) & x ( 2 ) & … & x ( p + 1 ) \\ x ( 2 ) & x ( 3 ) & … & x ( p + 2 ) \\ ⋮ & ⋮ & & ⋮ \\ x ( N - p ) & x ( N - p + 1 ) & … & x ( N )\end{matrix} ]$$

If the sampled signal x∈C^{N} is the sum of M damped exponentials, by choosing p∈[M,N−M], the Hankel matrix generally becomes a matrix of rank M≤p, i.e., low-rank. In the noiseless case, the matrix pencil algorithm exploits this low-rank Hankel matrix to accurately estimate the exponentials parameters. Thus, in this work, we aim to extract such a low-rank Hankel matrix, Hₚ(x), where x is the estimated sum of damped exponentials, using the observation Hankel matrix Y=H_{P}(y)∈C^{(N-p)×(p+1)}, where y∈C^{N} is the sampled noisy observation. In addition, we should be able to further extract a sparse matrix if spike interference exists. We rely on the assumption that M is small relative to N. Since p is fixed during the optimization process, we simplify notation using H(x) and dropping the subscript p. Inspired by the success of the robust principal component analysis and work in the compressive sensing community, we apply the nuclear norm to constrain the rank of H(x) and use the L1 norm to extract the sparse matrix S caused by the spike interference. We assume the residual represents the Gaussian noise. Combining those models results in the following convex robust parameter estimation (CRPE) problem

$${min}_{x , S} \frac{1}{2} {‖ Y - H ( x ) - S ‖}_{2}^{2} + {λ}_{1} {‖ H ( x ) ‖}_{*} + {λ}_{2} {‖ S ‖}_{1} . \qquad ( 2 )$$

Alternatively, the non-convex robust parameter estimation (NRPE), replaces nuclear norm regularization with a rank constraint:

$${min}_{x , S} \frac{1}{2} {‖ Y - H ( x ) - S ‖}_{2}^{2} + {λ}_{2} {‖ S ‖}_{1} \\ subject to Rank ( H ( x ) ) \leq r \qquad ( 3 )$$

where r denotes the maximum number of damped exponentials we expect to recover. If we have a prior estimate or knowledge of the number of damped exponentials, based on the nature of the application, r can be set greater than or equal to that estimate. Accordingly, some embodiments of the present invention are based on recognition that the NRPE optimization problem to be less sensitive to the hyper-parameters compared to the CRPE optimization problem. However, since (3) is non-convex, the optimization algorithm could get trapped in local minima.

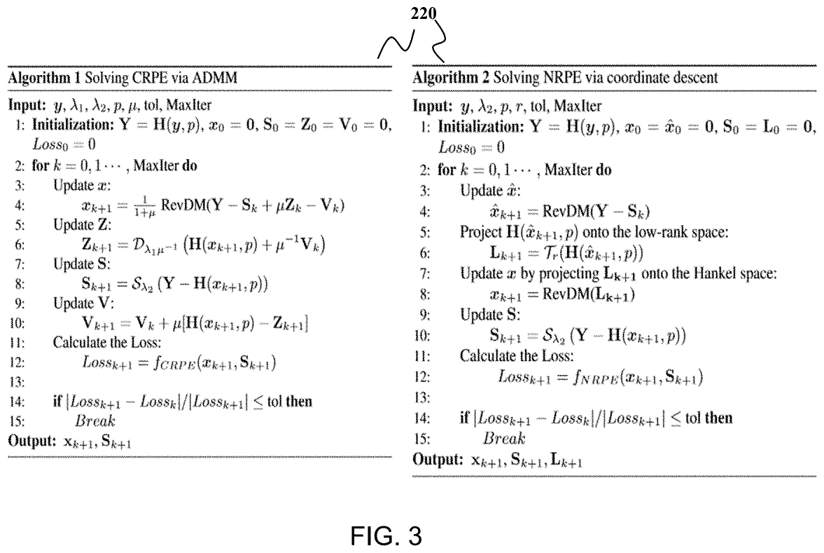

To solve the CRPE optimization problem, we introduce an auxiliary variable Z and add the constraint H(x)=Z to (2). Then the augmented Lagrangian function of (2) becomes

$${ℒ}_{μ} ( x , S , Z , V ) = \frac{1}{2} {‖ Y - H ( x ) - S ‖}_{2}^{2} + {λ}_{1} {‖ Z ‖}_{*} + {λ}_{2} {‖ S ‖}_{1} + {〈 H ( x ) - Z , V 〉}_{R} + \frac{μ}{2} {‖ H ( x ) - Z ‖}_{2}^{2} ,$$

where V∈C^{(N-p)×(p+1)} is the Lagrange multiplier matrix, μ is the penalty parameter associated with the augmented term, and) [symbol] A,B [symbol] _{R}=Re(Tr(B^{H}A)). Applying ADMM results in the update steps summarized in Algorithm 1 as shown in FIG. 3(a).

The Reverse Diagonal Mean Operator (RevDM: C^{(N-p)×(p+1)}→C^{N}) is defined as

$$RevDM ( A ) = [ \begin{matrix}A ( 1 , 1 ) \\ \frac{1}{2} [ A ( 2 , 1 ) + A ( 1 , 2 ) ] \\ \frac{1}{3} [ A ( 3 , 1 ) + A ( 2 , 2 ) + A ( 1 , 3 ) ] \\ ⋮ \\ A ( N - p , p + 1 )\end{matrix} ]$$

for A∈C^{(N-p)×(p+1)} and A(i; j) is the entry of A in the i-th row and j-th column. S_{τ}(A)=sign(A)max{|A|−τ,0} is the complex element-wise soft thresholding operator with threshold [symbol] , where sign(A)=A/|A| for the non-zero entry and 0 otherwise. max{⋅,⋅} is the element-wise maximum operator. Moreover, [symbol] _{τ}(A)=U diag(max{σ−τ,0})W^{H} is the singular value soft thresholding operator with threshold [symbol] , where the singular value decomposition of A=U diag(σ)W^{H}, ƒ_{CRPE} is the objective function of the CRPE optimization problem defined in (2).

The solver for the NRPE optimization problem, summarized in Algorithm 2, is based on the coordinate descent with projection. Tr(A) is the singular value truncation operator, which implements the singular value decomposition on the input matrix A and returns the matrix constructed using A's r largest singular values. ƒ_{NRPE} is the objective function of the NRPE optimization problem in (3). In the first experiment, we consider the bearing fault detection of the induction machine, where the machine current includes a 60 Hz operating signal and a 90 Hz sideband wave related to its rotational frequency component in the presence of Gaussian noise and spike interference. When a bearing fault or defect occurs, a damped frequency component in the current will be generated that depends on the fault location and the bearing size. For example, a 73 Hz frequency component is caused by the cage defect of an outer ring. The magnitude of this defect frequency component is typically very small compared to the operating current signal, making bearing fault detection a very challenging problem. Still, its parameters, and sometimes the spike interference, are useful to evaluate the fault severity and operating condition of the machine.

The noisy fault observation is formulated as follows:

γ(t)=e^{0t}1.0 cos(2π60t+1.3)+e^{-4.2}0.1 cos(2π73t+0.2)+e^{-1.3t}0.3 cos(2π90t+1.7)+g(t)+s(t).

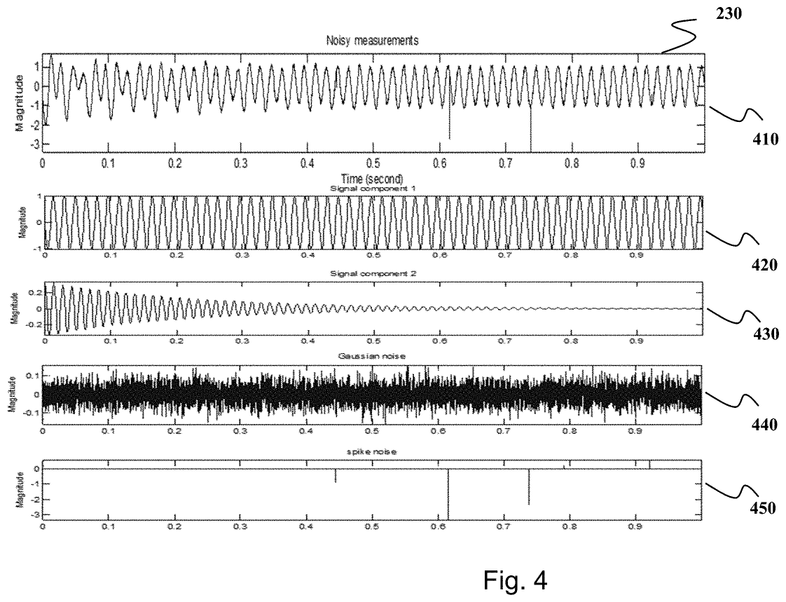

We observe 1 second of y with 1000 samples. The signal to Gaussian noise ratio is 25 dB and spike interference has 1% cardinality whose non-zero entries are randomly selected with magnitudes uniformly sampled in [0, 5]. We plot in FIG. 4 an example signal of a stator current 410 powering the electric machine and demixed damped signals. Using a matrix pencil method on a denoised Hankel matrix, the noisy measurement is demixed into a fundamental operating frequency component 420, a fault signature damped signal 430, a Gaussian noise 440, and a spike interference 450.

The above-described embodiments of the present disclosure can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the programs may be combined or distributed as desired in various embodiments. In some cases, computer-implemented programs used in the embodiments of the present invention may be referred to as program modules or modules.

Further, the embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments. Further, use of ordinal terms such as first, second, in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

1. A system for detecting faults of an electric machine, comprising:
an interface configured to acquire signals via sensors with respect to the machine for an input time domain;
a memory to store computer-implemented programs including a signal sampling program, a matrix formation program, an optimization formation program, a matrix pencil program, optimization solvers and lookup data including predetermined system parameters related to the faults; and
a processer, when performing the computer-implemented programs in connection with the interface and the memory, configured to perform:
generating a signal matrix based on the acquired signals for the input time domain;
forming an optimization problem with a low-rank constraint using the optimization formation program;
demixing the signal matrix into a low-rank matrix, a spike interference matrix, and a Gaussian noise matrix by solving the optimization problem using one of the optimization solvers;
extracting parameters of damped exponentials from the low-rank matrix using the matrix pencil program; and
determining the faults with respect to the induction machine by identifying each of the measured system parameters of the induction machine based on the lookup data.

2. The system of claim 1, wherein the optimization formation program generates a convex robust parameter estimation (CRPE) optimization problem or a non-convex robust parameter estimation (NRPE) optimization problem.

3. The system of claim 1, wherein the optimization solvers are based on a convex robust parameter estimation (CRPE) method and a non-convex robust parameter estimation (NRPE) method.

4. The system of claim 1, wherein the input time domain represents a sampling period and a sampling frequency.

5. The system of claim 1, wherein the matrix pencil program is configured to obtain eigenvalues and compute damping factor and frequency using the eigenvalues.

6. The system of claim 1, wherein the acquired signals are current signals or vibration signals based on operations of the electric machine.

7. The system of claim 1, wherein the low-rank matrix is Hankel matrix.

8. The system of claim 1, wherein the electric machine is an electric circuit, an electric motor or an electric generator.

9. A method for detecting faults of an electric machine, comprising:
acquiring signals via sensors with respect to the machine for an input time domain;
generating a signal matrix based on the acquired signals for the input time domain;
forming an optimization problem with a low-rank constraint using an optimization formation program;
demixing the signal matrix into a low-rank matrix, a spike interference matrix, and a Gaussian noise matrix by solving the optimization problem using one of optimization solvers;
extracting parameters of damped exponentials from the low-rank matrix using the matrix pencil program; and
determining the faults with respect to the induction machine by identifying each of the measured system parameters of the induction machine based on the lookup data.

10. The method of claim 9, wherein the optimization formation program generates a convex robust parameter estimation (CRPE) optimization problem or a non-convex robust parameter estimation (NRPE) optimization problem.

11. The method of claim 9, wherein the optimization solvers are based on a convex robust parameter estimation (CRPE) method and a non-convex robust parameter estimation (NRPE) method.

12. The method of claim 9, wherein the input time domain represents a sampling period and a sampling frequency.

13. The method of claim 9, wherein the matrix pencil program is configured to obtain eigenvalues and compute damping factor and frequency using the eigenvalues.

14. The system of claim 1, wherein the acquired signals are current signals or vibration signals based on operations of the electric machine.

15. The system of claim 1, wherein the low-rank matrix is Hankel matrix.

16. The system of claim 1, wherein the electric machine is an electric circuit, an electric motor or an electric generator.
